(19) United States
(12) Patent Application Publication
(10) Pub. No.: US 2016/0334992 A1
(43) Pub. Date: Nov. 17, 2016

(54) SEMICONDUCTOR DEVICE THAT CHANGES A TARGET MEMORY UNIT BASED ON TEMPERATURE

(71) Applicant: KABUSHIKI KAISHA TOSHIBA, Tokyo (JP)

(72) Inventor: Noboru YASHIRO, Kawasaki Kanagawa (JP)

(21) Appl. No.: 15/051,221

(22) Filed: Feb. 23, 2016

(30) Foreign Application Priority Data
May 12, 2015 (JP) 2015-097593

(51) Int. Cl. G06F 3/06; G11C 16/10

(52) U.S. Cl. CPC G06F 3/0604; G11C 16/10; G06F 3/0653; G06F 3/0659; G06F 3/0688

(57) ABSTRACT

A semiconductor device connectable to a host includes a plurality of semiconductor memory units, which includes first and second memory units, a temperature sensing unit, and a controller. The temperature sensing unit is configured to detect temperatures of the plurality of semiconductor memory units, and includes a first sensor positioned to detect a temperature of the first memory unit, as a first temperature, and a second sensor positioned to detect a temperature of the second memory unit, as a second temperature. The controller is configured to receive a command to access the first memory unit from the host, and in response to the command, access the second memory unit and not the first memory unit, when the first temperature is higher than a first predetermined value and the second temperature is lower than a second predetermined value.

### CROSS-REFERENCE TO RELATED APPLICATION

This application is based upon and claims the benefit of priority from Japanese Patent Application No. 2015-097593; filed May 12, 2015, the entire contents of which are incorporated herein by reference.

### FIELD

Embodiments described herein relate generally to a semiconductor device.

### BACKGROUND

A semiconductor device of one type has a controller and a plurality of memory units.

### DESCRIPTION OF THE DRAWINGS FIG. 1 is a perspective view of a system in which a semiconductor device according to a first embodiment is installed.

FIG. 2 is a partially transparent perspective view of a host device in which the semiconductor device is installed.

FIG. 3 is a partially cross-sectional view of a tablet section of the host device shown in FIG. 2.

FIG. 4 illustrates the semiconductor device according to the first embodiment, where (a) is a front view thereof, (b) is a rear view thereof, and (c) is a side view thereof.

FIG. 5 is a block diagram of the semiconductor device according to the first embodiment.

FIG. 6 is a cross-sectional view of a NAND memory and a controller in the semiconductor device.

FIG. 7 is a block diagram of the controller.

FIG. 8 is a flowchart illustrating command processing performed by the semiconductor device according to the first embodiment.

FIG. 9 illustrates NAND memories and temperature sensors arranged on a substrate of the semiconductor device.

FIG. 10 is a block diagram of the controller according to a second embodiment.

FIG. 11 is a flowchart illustrating command processing performed by a semiconductor device according to the second embodiment.

### DETAILED DESCRIPTION

In general, according to an embodiment, a semiconductor device connectable to a host includes a plurality of semiconductor memory units, which includes first and second memory units, a temperature sensing unit, and a controller. The temperature sensing unit is configured to detect temperatures of the plurality of semiconductor memory units, and includes a first sensor positioned to detect a temperature of the first memory unit, as a first temperature, and a second sensor positioned to detect a temperature of the second memory unit, as a second temperature. The controller is configured to receive a command to access the first memory unit from the host, and in response to the command, access the second memory unit, not the first memory unit, when the first temperature is higher than a first predetermined value and the second temperature is lower than a second predetermined value.

Hereinafter, embodiments will be described with reference to drawings.

In the present specification, some elements may be described with a plurality of expressions. Further, these expressions are just examples, and the elements may be described with different expressions. Furthermore, elements, which are not described with a plurality of expressions, may be described with a plurality of expressions.

The drawings are schematic, and thicknesses and dimensions of elements, scales of thicknesses of layers, and the like may not exactly reflect those in an actual device. In addition, between the drawings, the dimensions and the scales may be mutually different.

### First Embodiment

FIGS. 1 to 3 show semiconductor devices 1 according to the first embodiment and a system 100 in which the semiconductor devices 1 are included. The system 100 is an example of an “electronic device”. The semiconductor device 1 is an example of a “semiconductor module” and a “semiconductor storage device”. The semiconductor device 1 according to the present embodiment is a memory system such as a solid state drive (SSD), and is not limited to this.

As shown in FIG. 1, the semiconductor devices 1 are built as storage devices into the system 100 such as a server. The system 100 includes the semiconductor devices 1 and a host device 2 on which the semiconductor devices 1 are mounted. The host device 2 includes, for example a plurality of connectors 3 (for example, slots) which are open upwardly. The plurality of semiconductor devices 1 is mounted on the connectors 3 of the host device 2, and is supported side by side to be erected in a substantially vertical direction. With such a configuration, the plurality of semiconductor devices 1 may be mounted together in a compact manner, and it is possible to reduce the size of the host device 2.

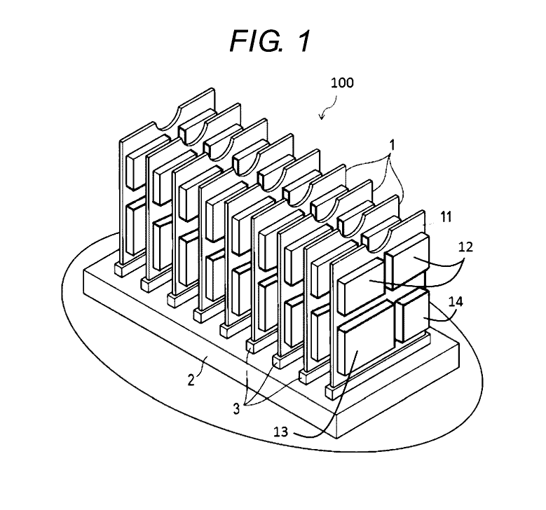

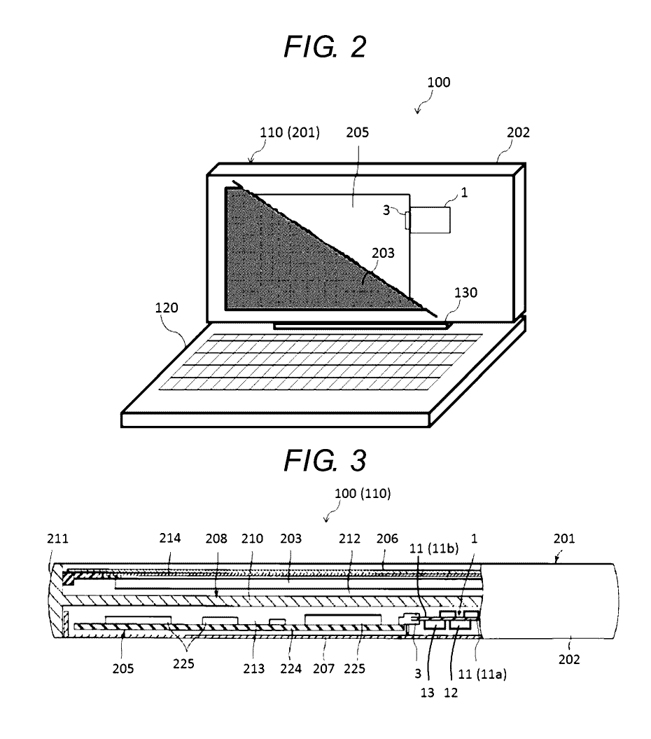

The semiconductor device 1 may serve as a storage device of an electronic device such as a notebook-type portable computer, a tablet terminal, or a detachable notebook personal computer (PC). In FIGS. 2 and 3, the semiconductor device 1 is mounted on a detachable notebook PC, which corresponds to the host device 2. Here, the whole system of the detachable notebook PC including the semiconductor device 1 corresponds to the system 100. Hereinafter, the semiconductor device 1 is mounted on the detachable notebook PC.

In FIG. 2, the semiconductor device 1 is mounted on the detachable notebook PC. FIG. 3 is a sectional view of a display section 110 (tablet-type portable computer 201) of the detachable notebook PC shown in FIG. 2. The detachable notebook PC is configured such that the display section 110 is detachably connected to a keyboard section 120, which is a first input device, through a connection portion 130. In addition, the portable computer 201 and the detachable notebook PC are examples of the host device 2.

As shown in FIGS. 2 and 3, the semiconductor device 1 is mounted on a display section of the detachable notebook PC. Hence, even when the display section 110 is detached, the display section 110 may function as the tablet-type portable computer 201, and functions as a second input device.

The portable computer 201 is an example of an electronic device, and has, for example, a size small enough to be handheld.

The portable computer 201 includes, as main elements, a casing 202, a display module 203, the semiconductor device 1, and a motherboard 205. The casing 202 includes a protective plate 206, a base 207, and a frame 208. The protective plate 206 is a square plate made of glass or plastic, and configures a surface of the casing 202. The base 207 is made of, for example, metal such as aluminum alloy or magnesium alloy, and configures the bottom of the casing 202.

The frame 208 is provided between the protective plate 206 and the base 207. The frame 208 is made of, for example, metal such as aluminum alloy or magnesium alloy, and integrally includes a mounting section 210 and a bumper section 211. The mounting section 210 is provided between the protective plate 206 and the base 207. According to the present embodiment, a gap between the mounting section 210 and the protective plate 206 is a first mounting space 212, and a gap between the mounting section 210 and the base 207 is a second mounting space 213.

The bumper section 211 is integrally formed on the outer peripheral edge of the mounting section 210, and consecutively surrounds the first mounting space 212 and the second mounting space 213 in a circumferential direction. Further, the bumper section 211 extends in a thickness direction of the casing 202 so as to bridge the gap between the outer peripheral edge of the protective plate 206 and the outer peripheral edge of the base 207, and configures the outer peripheral surface of the casing 202.

The display module 203 is accommodated in the first mounting space 212 of the casing 202. The display module 203 is covered with the protective plate 206, and a touch panel 214 having a handwriting input function is disposed between the protective plate 206 and the display module 203. The touch panel 214 is bonded to the rear side of the protective plate 206.

As shown in FIG. 3, the semiconductor device 1 is mounted together with the motherboard 205 in the second mounting space 213 of the casing 202. The semiconductor device 1 includes a substrate 11, NAND memories 12, a controller 13, and other electronic components such as a DRAM 14.

The substrate 11 is, for example, a printed-wiring board, and has a first surface 11a on which conductor patterns (not shown in the drawing) are formed and a second surface 11b opposite to the first surface 11a. Circuit components 225 are mounted on the first surface 11a and the second surface 11b of the substrate 11, and are soldered to the conductor patterns.

The motherboard 205 includes a plurality of circuit components 225 such as a substrate 224, semiconductor packages, and semiconductor chips. The plurality of conductive patterns (not shown in the drawing) is formed on the substrate 224. The circuit components 225 are mounted on the substrate 224, and are electrically connected to the conductive patterns of the substrate 224 with the solder.

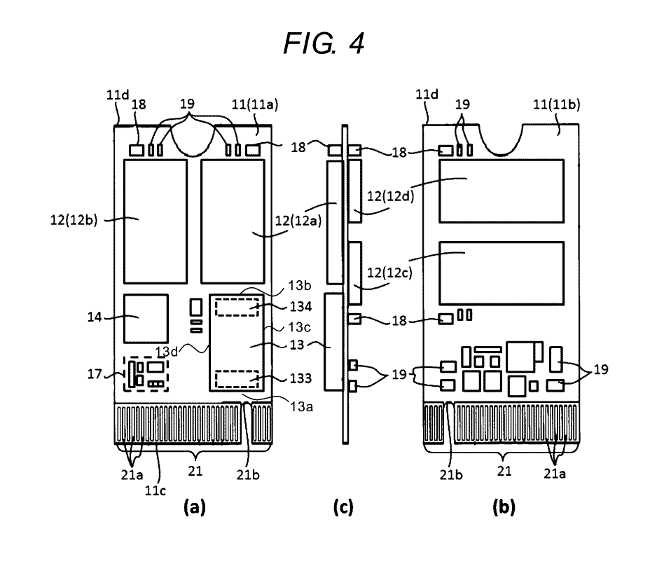

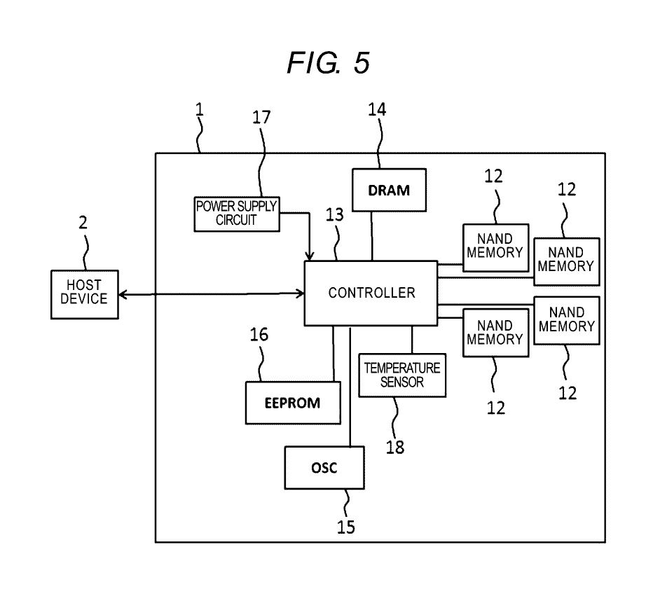

FIG. 4 illustrated the semiconductor device 1 from different angles. (a) of FIG. 4 is a plan view on a side of the first surface 11a, (b) of FIG. 4 is a plan view on a side of the second surface 11b, and (c) of FIG. 4 is a side view. Further, FIG. 5 shows an example of a system configuration of the semiconductor device 1. As shown in FIG. 4, the semiconductor device 1 includes a substrate 11, NAND flash memories (hereinafter abbreviated as NAND memories) 12 as nonvolatile semiconductor memory elements, a controller 13, a dynamic random access memory (DRAM) 14 as a volatile semiconductor memory element capable of performing faster a storing operation than that of the NAND memories 12, an oscillator (OSC) 15, an electrically erasable and programmable ROM (EEPROM) 16, a power supply circuit 17, temperature sensors 18, and other electronic components 19 such as a resistance and a capacitor.

The NAND memories 12 and the controller 13 according to the present embodiment each are mounted on the substrate 11 as a semiconductor package. For example, the semiconductor package of the NAND memory 12 is a system-in-package-type (SiP) module, and a plurality of semiconductor chips is enclosed in a single package. The controller 13 controls operations of the NAND memories 12.

The substrate 11 is, for example, a substantially rectangular circuit substrate formed of a material such as glass epoxy resin, and defines external dimensions of the semiconductor device 1. The substrate 11 has the first surface 11a and the second surface 11b opposite to the first surface 11a. In the present disclosure, surfaces of the substrate 11 other than the first surface 11a and the second surface 11b are defined as “side surfaces”. In the semiconductor device 1, the first surface 11a and the second surface 11b are component-mounted surfaces on which the NAND memories 12, the controller 13, the DRAM 14, the oscillator 15, the EEPROM 16, the power supply component 17, the temperature sensors 18, the other electronic components 19 such as a resistance and a capacitor, and the like are mounted.

The substrate 11 shown in FIG. 4 includes a first edge portion 11c and a second edge portion 11d opposite to the first edge portion 11c. The first edge portion 11c includes an interface section 21 (substrate interface portion, terminal portion, or connection portion). The interface section 21 includes, for example, a plurality of connection terminals 21a (metal terminals). The interface section 21 is inserted to, for example, the connector 3 of the host device 2, and is electrically connected to the connector 3. The interface section 21 exchanges signals (control signals and data signals) with the host device 2. In addition, the host device 2 described herein is, for example, the above-described portable computer 201.

The interface section 21 according to the present embodiment is, for example, an interface complying with the standard of PCI Express (hereinafter referred to as PCIe). That is, high-speed signals (high-speed differential signal) complying with the standard of the PCIe flow between the interface section 21 and the host device 2. It should be noted that the interface section 21 may comply with, for example, another standard. The semiconductor device 1 receives power from the host device 2 through the interface section 21.

In the interface section 21, a slit 21b is formed at a position offset from the center of the substrate 11 in a width direction, so as to be engaged with a protrusion (not shown FIG. 4), which is provided on the connector 3 of the host device 2. With the slit 21b, it is possible to prevent the semiconductor device 1 from being mounted in a reversed state.

The power supply circuit 17 is, for example, a DC-DC converter, and generates a predetermined voltage, which is necessary for the semiconductor package 12 to operate, using the power supplied from the host device 2. In addition, it is preferable that the power supply circuit 17 is provided near the interface section 21 in order to minimize a loss in the power supplied from the host device 2.

The controller 13 controls operations of the NAND memories 12. That is, the controller 13 controls writing, reading, and erasing of data in the NAND memories 12.

The DRAM 14 is an example of a volatile memory, and is used for storing administration information of the NAND memories 12, caching data, and the like. The oscillator 15 supplies an actuating signal of a predetermined frequency to the controller 13. The EEPROM 16 stores a control program and the like as fixed information.

The temperature sensor 18 outputs temperatures of the controller 13 and the NAND memories 12 to the controller 13. In the present embodiment, the number of the temperature sensors 18 is equal to that of the NAND memories 12. The temperature sensors 18 are mounted on the substrate 11 and detect the temperatures of the controller 13 and all the NAND memories 12, which are mounted on the semiconductor device 1. Although described below in detail, each of the NAND memories 12 is a semiconductor package, and has a structure in which a plurality of memory chips 32 is stacked. As described above, the number of the mounted temperature sensors 18 is equal to, for example, the number of the NAND memories 12 (the number of packages).

“The temperatures of the NAND memories 12” described herein are measured at positions where the temperature sensors 18 are mounted. The same is applicable for “the temperature of the controller 13”.

In the present embodiment, the mounting positions and the number of the NAND memories 12 are not limited to those shown in FIG. 4. In the present embodiment, the two NAND memories 12 (12a and 12b) are mounted on the first surface 11a of the substrate 11, and the two NAND memories 12 (12c and 12d) are mounted on the second surface 11b. However, for example, the number of the NAND memories 12 is not limited to this. Further, all the components on the substrate 11, which include the NAND memories 12, may be mounted only on the first surface 11a.

It is not necessary that the number of the temperature sensors 18, which detect the temperatures of the NAND memories 12, is equal to the number of the NAND memories 12. For example, a single temperature sensor 18 may detect temperatures of the plurality of NAND memories 12. In this case, it is preferable that the temperature sensor 18 is provided between the plurality of NAND memories 12. Further, it is not necessary to provide the temperature sensor 18 on the substrate 11, and the temperatures may be detected by the controller 13.

As described above, when all components on the substrate 11 are mounted only on the first surface 11a, the second surface 11b is a no-component-mounted surface on which no component is mounted. In this case, as compared with a case where components are disposed on both surfaces of the substrate 11, it is possible to reduce the thickness of the semiconductor device 1. Further, it is also possible to reduce the size and the thickness of the host device 201 such as the portable computer 201 on which the semiconductor device 1 is mounted.

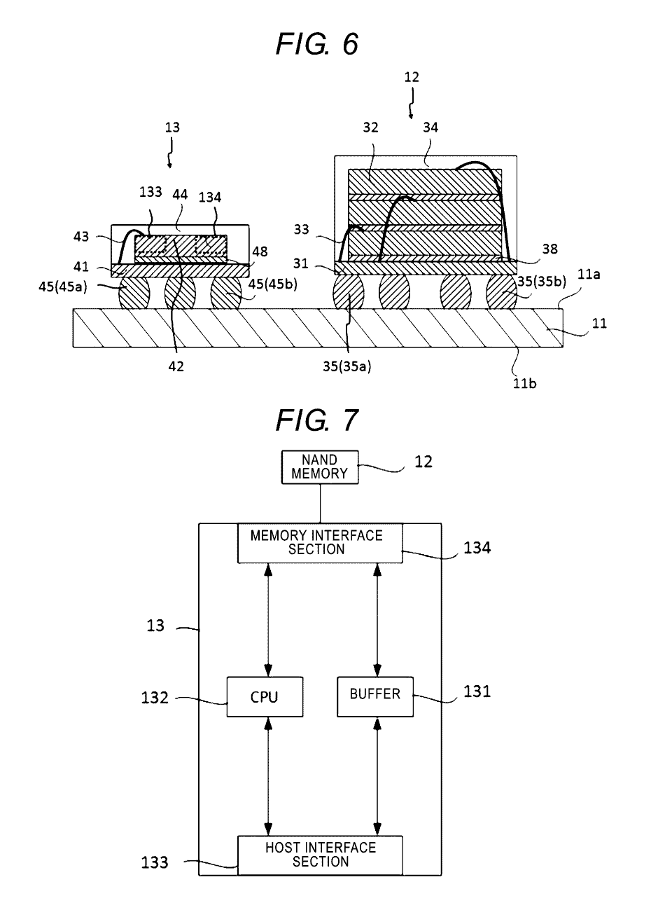

FIG. 6 shows a cross-sectional surface of a semiconductor package as the NAND memory 12 and a semiconductor package as the controller 13 in the present embodiment. The controller 13 includes a package substrate 41, a controller chip 42, a bonding wire 43, a sealing portion (mold material) 44, and a plurality of solder balls 45. The NAND memory 12 includes a package substrate 31, a plurality of memory chips 32, a bonding wire 33, a sealing portion (mold material) 34, and a plurality of solder balls 35.

The substrate 11 is, for example, a multilayer wiring substrate in the above-described example, and includes a power supply layer, a ground layer, and an internal wire (not shown). The controller chip 42 is electrically connected to the plurality of memory chips 32 through the bonding wires 33 and 43, the plurality of solder balls 35 and 45, and the like.

As shown in FIG. 6, the plurality of solder balls 35 and 45 are provided on the package substrates 31 and 41. The plurality of solder balls 35 and 45 is arranged in, for example, a lattice shape on the second surface 31b of the package substrate 31. Here, the plurality of solder balls 35 may not be arranged fully on the entire second surface 31b of the package substrate 31, and the solder balls 35 may be partially arranged.

A mount film 38 is used to fix the package substrate 31 and one of the memory chips (bottom chip) 32 and two adjacent memory chips 32. Similarly, a mount film 48 is used to fix the package substrate 41 and the controller chip 42.

As shown in FIG. 4, the controller 13 in the present embodiment is substantially rectangular. The controller 13 has a first edge portion 13a in a width direction, a second edge portion 13b opposite to the first edge portion 13a, a third edge portion 13c in a longitudinal direction, and a fourth edge portion 13d opposite to the third edge portion 13c. In addition, the second edge portion 13b is positioned to be close to an adjacent NAND memory 12 mounted on the substrate 11. The first edge portion 13a is positioned to be close to the interface section 21 of the substrate 11.

The solder balls 45 include solder balls 45a that are positioned to be close to the first edge portion 13a of the controller 13 and solder balls 45b that are positioned to be close to the second edge portion 13b. Further, the solder balls 35 include solder balls 35a that are positioned to be close to the controller 13 and solder balls 35b that are opposite to the solder balls 35a.

FIG. 7 shows an example of a system configuration of the controller 13. As shown in FIG. 7, the controller 13 includes a buffer 131, a central processing unit (CPU) 132, a host interface section 133, and a memory interface section 134. In addition, as described above, for example, the controller 13 may have a function of the temperature sensor 18, and may have a function of the power supply circuit 17. The system configuration of the controller 13 is not limited to this. The buffer 131 temporarily stores a certain amount of data when data sent from the host device 2 is written into the NAND memories 12, or temporarily stores a certain amount of data when data read from the NAND memories 12 is delivered to the host device 2.

The CPU 132 has a function of controlling the entire semiconductor device 1. The CPU 132 receives, for example, a writing command, a reading command, and a deleting command from the host device 2, accesses corresponding regions of the NAND memories 12, and controls data transfer processing through the buffer 131.

The host interface section 133 is positioned between the interface section 21 of the substrate 11 and the CPU 132 and between the interface section 21 and the buffer 131. The host interface section 133 performs interface processing between the controller 13 and the host device 2. For example, PCIe high-speed signals flow between the host interface section 133 and the host device 2.

The host interface section 133 is arranged to be close to the interface section 21 of the substrate 11 in the controller 13, that is, to be close to the first edge portion 13a. According to this arrangement, it is possible to shorten the wire between the host interface section 133 and the interface section 21 of the substrate 11.

For example, it is assumed that the host interface section 133 is arranged to be close to the side of the controller 13 opposite to the interface section 21, that is, to be close to the second edge portion 13b. In this case, as shown in FIG. 4, a distance of the wire connecting the interface section 21 and the host interface section 133 would increase by the length of the controller chip in the longitudinal direction. As the length of wire increases, a parasitic capacitance, a parasitic resistance, a parasitic inductance, and the like of the wire would increase. As a result, it would not be easy to maintain a characteristic impedance of the signal wire. Further, this may cause signal delay.

In view of the above, in the present embodiment, it is preferable that the host interface section 133 is arranged to be close to the first edge portion 31a in the controller 13. For example, when a command is sent from the host device 2, the interface section 21 receives signals from the host device 2, and exchanges signals with the host interface section 133 through the solder balls 45a, where the signal is sent from the wiring pattern of the substrate 11. Thereby, it is possible to improve operational stability of the semiconductor device 1.

It is preferable that an electronic component is not mounted between the host interface section 133 and the interface section 21 of the substrate 11.

As described above, when the distance of the wire between the host interface section 133 and the interface section 21 is long, problems may arise in the following points: it is not easy to maintain the impedance of the signal wire; and the long distance causes signal delay. Accordingly, in order to minimize the distance of the wire connecting the host interface section 133 and the interface section 21, that is, in order to make the wire linear, it is not preferable that an electronic component is mounted between the host interface section 133 and the interface section 21.

The electronic components such as the power supply circuit 17 and the DRAM 14 are likely to be affected by noise during the operation. When such electronic components are not between the host interface section 133 and the interface section 21, signals exchanging between the host interface section 133 and the interface section 21 are less likely to include noise. Thereby, it is possible to improve the operational stability of the semiconductor device 1.

The memory interface section 134 is positioned between the NAND memories 12 and the CPU 132 and between the NAND memories 12 and the buffer 131. The memory interface section 134 performs interface processing between the controller 13 and the NAND memories 12.

In the present embodiment, the memory interface section 134 is arranged to be close to the side of the controller 13 opposite to the interface section 21 of the substrate 11, that is, to be close to the second edge portion 13b. According to this arrangement, it is possible to shorten the distance of the wire between the memory interface section 134 and the NAND memories 12.

The signals sent from the controller 13 are transferred to the wiring pattern of the substrate 11 through the solder balls 45b, and then from the solder balls 35a to the memory chips 32. Thereby, by shortening the distance of the wire, the operational stability of the semiconductor device 1 can be improved.

In the present embodiment, the two NAND memories 12 mounted on the second surface 11b of the substrate 11 are also arranged to be close to the second edge portion of the substrate 11. Hence, when the wire leads to the second surface 11b from the controller 13 which is mounted on the first surface 11a of the substrate 11, it is also preferable that the memory interface section 134 is positioned to be close to the second edge portion 13b of the controller 13.

It is preferable that the power supply circuit 17, the DRAM 14, and the like are not mounted between the memory interface section 134 of the controller 13 and the NAND memories 12 on the substrate 11. According to such an arrangement, it is less likely that the signals exchanged between the memory interface section 134 and the interface section 21 include noise, and, as a result, the operational stability of the semiconductor device 1 can be improved.

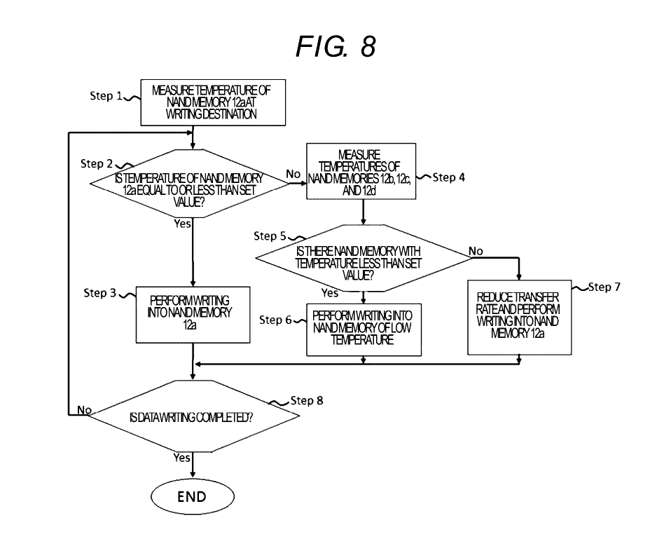

FIG. 8 is a flowchart illustrating an example of the command processing carried out by the semiconductor device, with respect to a command issued from the host of the controller 13 which is mounted on the semiconductor device 1 in the present embodiment. In the semiconductor device 1, the controller 13 receives a writing (recording) command, a reading (readout) command, an erasing (deleting) command, and the like from the host device 2. Hereinafter, it is assumed that the writing (recording) command is sent from the host device 2.

The above-described writing command includes the size of data to be processed by the host device 2 to be written in the semiconductor device 1, address information that indicates a position at which the data is to be written, and the like. For example, the semiconductor device 1 which receives the writing command accesses the NAND memory 12 and determines whether or not the data may be accepted. When the data may be accepted, that is, may be written, the semiconductor device 1 returns a response, which indicates that writing is possible, to the host device 2, and then receives data for writing (write data) from the host device 2. In the flowchart of FIG. 8, it is assumed that writing into the NAND memories 12 is possible, and the corresponding steps are omitted. Accordingly, a description will be given from a step where the controller 13 of the semiconductor device 1 receives the write data from the host device 2.

As described above, the controller 13 first receives the write data from the host device 2. In addition, the write data sent from the host device 2 is temporarily stored in the buffer 131. At this time, a storage unit is, for example, based on per page.

Next, data writing processing is performed on the NAND memory 12 which is designated by the host device 2 based on the previously received writing command. At this time, first, the temperature sensor 18 measures a temperature of the designated NAND memory 12 (Step 1).

In the present embodiment, the semiconductor device 1 includes the four NAND memories 12 (12a, 12b, 12c, and 12d). However, the host device 2 randomly designates, as a target NAND memory, one of the NAND memories 12 in which the write data is to be written when the host device 2 outputs the writing command. In the present embodiment, it is assumed that the NAND memory 12a is designated as the target NAND memory through the writing command sent from the host device 2.

After the temperature Ta of the NAND memory 12a is detected in Step 1, it is determined whether or not the temperature Ta of the NAND memory 12a is equal to or lower than a predetermined temperature Tt (for example, Tt=75° C.) (Step 2). When the temperature Ta of the NAND memory 12a is equal to or lower than the temperature Tt, writing into the NAND memory 12a is performed in accordance with to the writing command (Step 3).

In contrast, when the temperature Ta of the NAND memory 12a designated by the host device 2 is higher than the predetermined temperature Tt (for example, Tt=75° C.), the temperatures T (Tb, Tc, and Td) of other NAND memories 12 (12b, 12c, and 12d), which are not designated by the host device 2, are measured (Step 4). Then, it is determined whether there is a NAND memory 12 of which a temperature is lower than the temperature Tt (Step 5).

In Step 5, when there is a NAND memory 12 of which the temperature is lower than the temperature Tt (for example, only a temperature Td of the NAND memory 12d is assumed to be lower than the temperature Tt here), writing processing is performed on the NAND memory (NAND memory 12d here) (Step 6).

In contrast, when all temperatures Tb, Tc, and Td of the NAND memories 12b, 12c, and 12d are not lower than the temperature Tt, writing into the NAND memory 12a is performed in accordance with the writing command sent from the host device 2. At this time, the writing processing is performed at a writing speed (transfer rate) slower than that in Step 3, so that temperature increase of the NAND memory 12a is suppressed (Step 7).

When any of Steps 3, 6, and 7 is completed, the controller determines whether or not the writing processing corresponding to the writing command sent from the host device 2 is completed. That is, it is determined whether data to be processed does not remain in the controller 13 (Step 8).

When the writing of the data is not completed, returning to Step 2, processing of writing the remaining data is performed in accordance with the writing command. It should be noted here that the term “when the writing of the data is not completed” includes not only a case where the data processing (writing processing) in accordance with a single writing command sent from the host device 2 has not been completed, but also a case where a new command is sent from the host device 2 in the course of the data processing. That is, in Step 8, the controller 13 determines whether or not data to be processed is present.

In the present embodiment, the temperature sensors 18 (18a, 18b, 18c, and 18d) respectively detect the temperatures of the NAND memories 12 (12a, 12b, 12c, and 12d), and the controller 13 recognizes the detected temperatures of the NAND memories 12. When the temperature T (Ta) of the NAND memory 12 to be subjected to writing is higher than the predetermined temperature Tt, a NAND memory 12 of which the temperature is lower than the temperature Tt is selected among the other NAND memories 12, and writing is performed thereto. In particular, a NAND memory 12 (12d) with the lowest temperature is selected in the present embodiment, and writing processing is performed thereto.

In general, heat is generated in the controller chip 42 during an operation of the controller 13. The heat generated by the controller chip 42 is dissipated to the outside of the controller 13 through the sealing portion 44. Further, the heat generated in the controller chip 42 is dissipated to the substrate 11 through the package substrate 41 and the solder balls 45. The heat is dissipated to the other components on the substrate 11 including the NAND memories 12.

Accordingly, the temperatures of the NAND memories 12 may change by the effects of not only the heat generated thereby but also the heat conducted from the controller 13. Hence, when the plurality of NAND memories 12 is mounted on the semiconductor device 1, even when the load of the NAND memories 12 is uniform, the temperatures of the respective NAND memories 12 may not be uniform due to the wiring pattern on the substrate 11 and mounting positions of the respective NAND memories 12 on the substrate 11.

On the other hand, the NAND memories 12 are generally less resistant to heat, and operational capabilities thereof are changed by the ambient temperature. In particular, by continuously driving under a high-temperature environment, storage capacities of the NAND memories 12 may deteriorate.

To monitor the state of the controller 13, in the semiconductor device 1 such as a SSD in general, the temperature sensor 18 detects the temperature of (around) the controller 13. When the temperature of the controller 13 becomes high, the processing is performed on the NAND memories 12 at a slower transfer rate. Hence, when the temperature of the controller 13 becomes high, the processing is performed on all NAND memories 12 at the slower transfer rate. Thus, in some cases, operating characteristics of the semiconductor device 1 may deteriorate.

In contrast, in the present embodiment, the temperature sensors 18 monitor the temperatures of the NAND memories 12, the NAND memory 12 of a lower temperature is selected, and the processing is performed thereon. In other words, the semiconductor device 1 according to the present embodiment has the following configuration. The semiconductor device 1 includes the plurality of temperature sensors 18 that measure the temperatures of the plurality of NAND memories 12, selects one or more NAND memories 12 of which temperature are lower than a first value (a reference value, or a threshold value) among the NAND memories 12, and performs command processing on one of the selected NAND memories 12 having the lowest temperature (or the NAND memory 12 of which the temperature is a unique value less than a second value) among the selected NAND memories 12.

The controller 13 may not need to perform command processing on the NAND memories 12 at a lower transfer rate. Further, even when the temperatures of all NAND memories 12 are high, only the transfer rate of the NAND memory 12 as a processing target is reduced. Hence, the operating characteristics of the semiconductor device 1 may not need to be reduced too frequently.

In the present embodiment, Step 6 shows the example in which the writing processing is performed on the NAND memory 12d of a low temperature. However, when the temperatures of the NAND memories 12b and 12c are also lower than the temperature Tt, for example, any one of the NAND memories 12b, 12c, and 12d may be randomly selected, and writing processing may be performed thereon.

In Step 5, when the temperatures of the plurality of NAND memories 12 are lower than the temperature Tt, the NAND memory 12 of which the temperature is lowest may be selected, and the writing of Step 6 may be performed thereon. By selecting the NAND memory 12 with the lowest temperature and performing the writing processing thereon, a NAND memory 12, for which a time period required until the temperature T thereof reaches the temperature Tt is long, may be selected, and the frequency of changing of the NAND memory 12 to be subjected to writing may be reduced.

In the present embodiment, in Step 7, writing processing is performed on the NAND memory 12a at a lower transfer rate, in accordance with the command. Alternatively, when the temperatures of all NAND memories 12 are higher than the temperature Tt, the NAND memory as the writing target may be randomly selected.

As described above, the temperatures of the NAND memories 12 may change due to the heat dissipated from the controller 13. In the present embodiment, even when the load of all NAND memories 12 is the same, the temperature of the NAND memory 12a, which is closest to the controller 13, is most likely to increase, and is least likely to decrease. On the other hand, the temperature of the NAND memory 12d, which is farthest from the controller 13, is less likely to be affected by the heat of the controller 13. Hence, the temperature is less likely to increase and is more likely to decrease.

Hence, inmost cases, the temperature of the NAND memory 12d may be lowest among those of all the NAND memories 12. In this case, in Step 6, writing may not be performed on the NAND memory 12d, and instead the writing target may be randomly selected, whereby it is possible to contribute to leveling of the numbers of the writing processing on the NAND memories 12.

In general, when a NAND memory is continuously driven under a high temperature environment as described above, operating characteristics thereof may deteriorate. However, the deterioration of a NAND memory is caused by not only the temperature but also the number of writing operations. That is, the operating characteristics of a NAND memory may deteriorate in accordance with an increase in the number of writing operations.

In the present embodiment, in Steps 6 and 7, by randomly selecting the NAND memory 12 as a writing target, the number of operations of writing into each of the NAND memories 12 can be more uniform and a particular NAND memory 12 may not be selected as the writing target too frequently based on a positional relationship between the particular NAND memory 12 and the controller 13. As a result, this configuration may contribute to leveling of the deterioration of the NAND memories 12.

In the above description of the present embodiment, both the (threshold) temperature used in Step 2 and the (threshold) temperature used in Step 5 are set as the temperature Tt (for example, Tt=75° C.). However, the (threshold) temperatures used in Step 2 and Step 5 may be different.

For example, the temperature used in Step 5 may be set as a temperature Tt2 (for example, Tt2=70° C.), which is lower than the temperature Tt (Tt=75° C.). In this case, the temperature of the NAND memory 12 on which writing processing is performed in Step 6 is lower than a temperature (in the embodiment, Tt=75° C.) at which writing processing is possible. Thus, it is possible to extend a time period required until the temperature of the NAND memory 12 as a writing target reaches the temperature Tt, and it is also possible to extend a time period during which the temperatures of the other NAND memories 12 decrease.

In the above description, the writing processing is exemplified, but the processing is not limited thereto, and the processing may be erasing (e.g., block erasing during garbage collection).

In the present embodiment, the four NAND memories 12 are exemplified. However, when the number of the NAND memories 12 is large, the following configuration may be adopted: a temperature sensor 18 is arranged between two NAND memories 12, so as to detect temperatures of the two NAND memories 12.

Further, temperature of a single NAND memory 12 may be representative of temperatures of a plurality of NAND memories 12 depending on a positional relationship between the NAND memories 12 and the controller 13 mounted on the substrate 11.

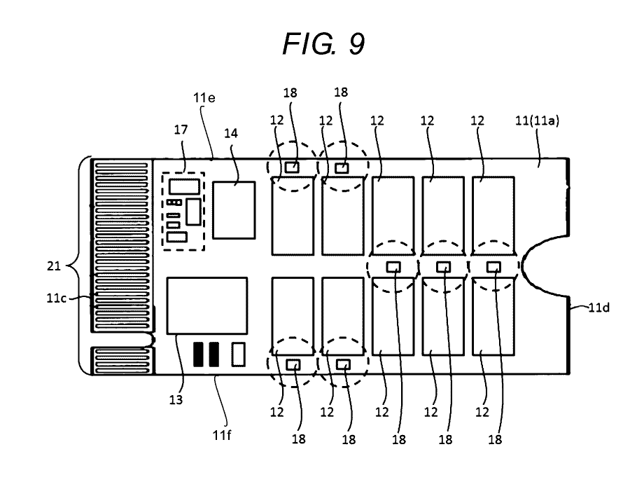

FIG. 9 shows an example in which the 10 NAND memories 12 are mounted on the first surface 11a of the substrate 11. In FIG. 9, each region surrounded by a dashed line is a region in which the temperature sensor 18 positioned therein can detect temperature.

In FIG. 9, four temperature sensors 18 disposed near the first edge portion 11c of the substrate 11 each detect temperature of a NAND memory 12. Here, the number of the temperature sensors 18 is equal to the number of the NAND memories 12. In contrast, three temperature sensors 18 disposed neat the second edge portion 11d of the substrate and between two adjacent NAND memories 12 of six NAND memories 12 detect temperatures of the two adjacent NAND memories 12.

As described above, when the controller 13 generates heat, the generated heat may be diffused toward the NAND memories 12. Thus, the NAND memories 12 (in FIG. 9, the NAND memories 12 positioned near the first edge portion 11c) closer to the controller 13 are more likely to be affected by the heat than the NAND memories 12 (in FIG. 9, the NAND memories 12 positioned near the second edge portion 11d) further from the controller 13.

Here, in the long axis of the substrate 11, an edge portion (the upper edge portion in FIG. 9) close to the power supply circuit 17 is referred to as a third edge portion 11e, and an edge portion (the lower edge portion in FIG. 9) close to the controller 13 is referred to as a fourth edge portion 11f. The controller 13 is arranged near the fourth edge portion 11f. Hence, focusing on the pair of the NAND memories 12 arranged in the direction of the shorter edges of the substrate 11, the NAND memory 12, which is positioned to be closer to the third edge portion 11e, is further from the controller 13.

Also, among a pair of NAND memories 12 arranged near the second edge portion 11d of the substrate 11, the NAND memory 12 positioned to be closer to the third edge portion 11e is further from the controller 13. However, in this case, as compared with the pair of NAND memories 12 positioned to be closer to the first edge portion 11c, a ratio of distances between the controller 13 and each of the two NAND memories 12 is smaller. That is, in FIG. 9, among sets of the two NAND memories 12 arranged in the direction of the shorter edges, temperatures of the two NAND memories 12 closer to the second edge portion 11d may be reliably detected by a single temperature sensor 18.

In summary, when the area of the substrate 11 is large and many NAND memories 12 are mounted thereon, a temperature difference between high-temperature NAND memories 12 and low-temperature NAND memories 12 may be more remarkable. However, as to a plurality of NAND memories 12 sufficiently far from the controller 13, temperature differences therebetween may be small. As a result, a single temperature sensor 18 may be able to collectively detect temperature of these NAND memories 12.

Thereby, when the number of the mounted NAND memories 12 is large, it is possible to reduce the number of the temperature sensors 18. Thus, space for mounting the NAND memories 12 and space for wiring on the substrate 11 may be secured.

In the example of the above description, the temperature sensors 18 are provided on the substrate 11. Alternatively, the temperature sensors 18 maybe provided on the NAND memories 12. Specifically, the temperature sensors 18 may be provided on surfaces of the sealing portions 34 of the NAND memories 12 or inside the sealing portion 34.

The temperature sensors 18 measure the temperatures of the NAND memories 12 in Steps 1 and 4 of FIG. 8. Here, the temperature sensors 18 may be configured such that the controller 13 recognizes at least temperatures of the NAND memories 12 which can be subjected (or may be subjected) to the command processing. Further, the temperature sensors 18 may measure temperatures of the NAND memories 12 all the time or at a predetermined cycle (for example, for every few seconds).

### Second Embodiment

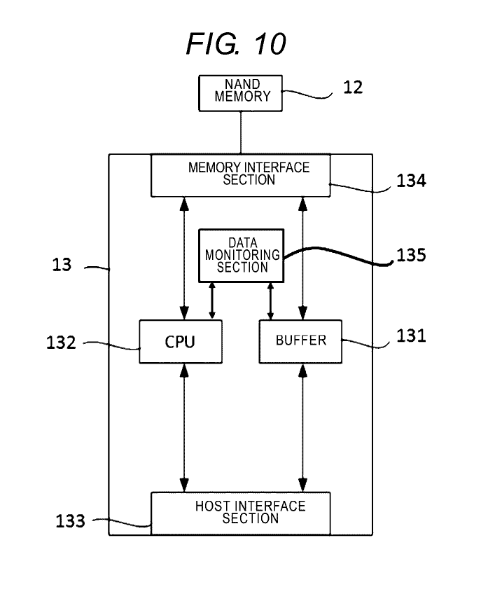

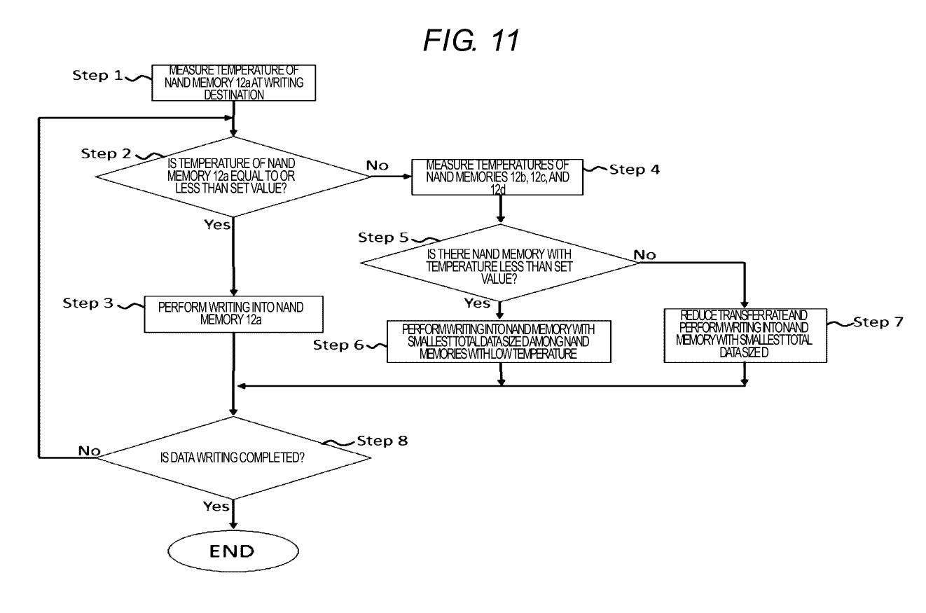

FIG. 10 shows an example of a system configuration of the controller 13 mounted on the semiconductor device 1 according to a second embodiment. FIG. 11 is a flowchart illustrating an example of the command processing performed by the controller 13 mounted on the semiconductor device 1 according to the second embodiment, with respect to the command issued from the host of the controller 13. In the description of the present embodiment, components common to the first embodiment will be represented by the same reference numerals and signals, and a detailed description thereof will be omitted. In the present embodiment, an appearance and a configuration of the semiconductor device 1 is the same as those in FIG. 4. As shown in FIG. 10 in the present embodiment, the controller 13 further includes a data monitoring section 135. The data monitoring section 135 monitors (tracks), for example, size of data (total size D) written into the NAND memories 12.

In the semiconductor device 1, the controller 13 receives a writing (recording) command, a reading (readout) command, an erasing (deleting) command, and the like from the host device 2. Hereinafter, similarly to the first embodiment, it is assumed that the writing (recording) command is sent from the host device 2.

The controller 13 first receives data for writing from the host device 2. Next, data writing processing is performed on the NAND memory 12 which is designated by the host device 2 based on the previously received writing command. At this time, first the temperature of the designated NAND memory 12 is measured (Step 1).

In the present embodiment, the semiconductor device 1 includes the four NAND memories 12 (12a, 12b, 12c, and 12d). However, the host device 2 randomly designates a NAND memory 12 in which data are to be written when the host device 2 outputs the writing command. In the present embodiment, it is assumed that writing into the NAND memory 12a is designated through the command sent from the host device 2.

The temperature of the NAND memory 12a is measured in Step 1, and it is determined whether or not the temperature T (Ta) of the NAND memory 12a is equal to or lower than a predetermined temperature Tt (for example, Tt=75° C.) (Step 2). When the temperature Ta of the NAND memory 12a is equal to or lower than the temperature Tt, writing into the NAND memory 12a is performed in accordance with the command (Step 3).

In contrast, when the temperature Ta of the NAND memory 12a designated by the host device 2 is higher than the predetermined temperature Tt (for example, Tt=75° C.), the temperatures T (Tb, Tc, and Td) of other NAND memories 12 (12b, 12c, and 12d) , which are not designated by the host device 2, are measured (Step 4). Thereafter, it is determined whether or not there is a NAND memory 12 of which the temperature is lower than the temperature Tt, among the NAND memories 12 which are not designated by the host device 2 (Step 5).

In Step 5, when at least one of the temperatures T (Tb, Tc, and Td) of the NAND memories 12 (12b, 12c, and 12d) other than the NAND memory 12a is lower than the temperature Tt, writing is performed on one of the NAND memories 12.

At this time, if temperatures of more than two NAND memories 12 are lower than the temperature Tt, the controller 13 determines the total data sizes D (Da, Db, Dc, and Dd) of data written in the respective NAND memories 12 based on monitoring result of the data monitoring section 135. Then, the controller 13 selects a NAND memory 12 of the smallest total data size among the NAND memories 12 (12b, 12c, and 12d) to be subjected to writing, and performs writing processing thereon (Step 6).

In contrast, when the temperature Td of the NAND memory 12d, which is the lowest temperature, is not lower than the temperature Tt, the total data sizes D (Da, Db, Dc, and Dd) of the respective NAND memories 12 are monitored by the data monitoring section 135. Then, the NAND memory 12 of the smallest total data size is selected among the NAND memories 12 (12a, 12b, 12c, and 12d) to be subjected to writing, and writing processing is performed on the NAND memory 12. At this time, the writing processing is performed at a lower writing speed (transfer rate) (Step 7). Thereby, an increase in temperature of the NAND memory 12a is suppressed.

The “total data size D” described herein is, for example, a total size of data written into the NAND memory 12 after use of the semiconductor device 1 is started. In this case, the following configuration may be adopted: the total data size D of the NAND memory 12 acquired by the data monitoring section 135 is retained in a certain NAND memory 12 each time the data monitoring section 135 acquires the data size. In addition, the following configuration may also be adopted: the total data size is retained in the buffer 131 when the semiconductor device 1 is activated, and the total data size is transferred to the NAND memory 131 before the power of the semiconductor device 1 and the host device 2 is turned off.

The “total data size D” may be a total size of data written into each NAND memory 12 after the power of the semiconductor device 1 is turned on until the power of the semiconductor device 1 is turned off. In such a configuration, the information of the total data size D is used only in Steps 6 and 7. Therefore, it is not always necessary to store the information in a nonvolatile manner (to store the information in the NAND memory 12).

When each of Steps 3, 6, and 7 is completed, the controller 13 determines whether or not writing processing in accordance with the command sent from the host device 2 is completed. That is, it is determined whether data to be processed does not remain in the controller 13 (Step 8).

When the writing of the data is not completed, returning to Step 2, processing of writing the remaining data is performed in accordance with the command. It should be noted here that “when the writing of the data is not completed” includes not only a case where the data processing (writing processing) in accordance with the commands sent from the host device 2 is not completed, but also a case where a new command is sent from the host device 2 in the course of the data processing. That is, in Step 8, the controller 13 determines whether or not data to be processed is present.

In the present embodiment, the temperature sensors 18 (18a, 18b, 18c, and 18d) respectively detect the temperatures of the NAND memories 12 (12a, 12b, 12c, and 12d), and the controller 13 recognizes the temperatures of the NAND memories 12. When the temperature T (Ta) of the NAND memory 12 to be subjected to writing is higher than the predetermined temperature Tt, another NAND memory 12 of lower temperature is selected, and writing processing is performed thereon.

Hence, it may not need to reduce the transfer rate of the command processing. Further, even when the temperatures of all the NAND memories are high, only the transfer rate of the NAND memory as a processing target can be reduced. Hence, it is possible to prevent deterioration in operating characteristics of the semiconductor device 1.

In the present embodiment, the controller 13 includes the data monitoring section 135. Thus, in Steps 6 and 7, the controller 13 selects the NAND memory 12 into which data of the smallest total data size D is written, among the NAND memories 12 to be subjected to writing, and performs writing processing thereon. In other words, the command processing is performed based on not only the temperatures of the NAND memories 12 but also the total data sizes (for example, first to fourth data sizes) of the four NAND memories 12.

The semiconductor device 1 according to the present embodiment can prevent the writing processing from being concentrated on a specific NAND memory 12 of which the temperature is less likely to increase and more likely to decrease. Thereby, it is possible to prevent the specific NAND memory 12 from being deteriorated by an increase in temperature, and it is also possible to prevent the specific NAND memory 12 from being deteriorated by deviation in the number of writing operations.

The semiconductor device 1 may be configured to perform, for example, operations according to the first embodiment for a predetermined time period (which is determined based on, for example, the number of operations of writing into the NAND memories 12) after the NAND memories 12 become in use (after the semiconductor device 1 is newly produced), and to perform operations according to the second embodiment after the predetermined time period. Further, as necessary, the total data sizes D, which are monitored by the data monitoring section 135, may be retained in the buffer 131 of the controller 13, and may be stored in the NAND memories 12 in a nonvolatile manner.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device connectable to a host, comprising:
a substrate;
a plurality of semiconductor memory units disposed on the substrate, which includes first and second memory units;
a temperature sensing unit configured to detect temperatures of the semiconductor memory units, the temperature sensing unit including a first sensor positioned to detect a temperature of the first memory unit, as a first temperature, and a second sensor positioned to detect a temperature of the second memory unit, as a second temperature; and
a controller configured to receive a command to access the first memory unit from the host, and in response to the command, access the second memory unit and not the first memory unit, when the first temperature is higher than a first predetermined value and the second temperature is lower than a second predetermined value.

2. The semiconductor device according to claim 1, wherein
the first predetermined value is equal to the second predetermined value.

3. The semiconductor device according to claim 1, wherein
the first predetermined value is higher than the second predetermined value.

4. The semiconductor device according to claim 1, wherein
in response to the command, the controller is configured to access the first memory unit at a first data transfer rate, when the first temperature is lower than the first predetermined value, and at a second data transfer rate that is lower than the first data transfer rate when the temperatures of the semiconductor memory units are all higher than the second predetermined value.

5. The semiconductor device according to claim 1, wherein
the second temperature has the lowest of temperatures detected by the temperature sensing unit.

6. The semiconductor device according to claim 1, wherein
the controller is further configured to determine a total data size of data that have been written in each of the plurality of semiconductor memory units since a predetermined time.

7. The semiconductor device according to claim 6, wherein
the total data size of data that have been written in the second memory unit is the smallest of the total data sizes that have been written in the semiconductor memory units.

8. The semiconductor device according to claim 6, wherein
in response to the command, the controller is configured to
access the first memory unit at a first data transfer rate, when the first temperature is lower than the first predetermined value, and
access one of the plurality of semiconductor memory units for which the total data size of data that have been written therein is the smallest, at a second data transfer rate that is slower than the first data transfer rate, when the temperatures of the plurality of semiconductor memory units are all higher than the second predetermined value.

9. The semiconductor device according to claim 1, wherein
the first sensor is positioned on the first memory unit, and the second sensor is positioned on the second memory unit.

10. A method for processing a command to access one of a plurality of semiconductor memory units, which includes first and second memory units, the method comprising:
measuring temperatures of the semiconductor memory units;
receiving a command to access the first memory unit from a host; and
in response to the command, accessing the second memory unit and not the first memory unit, when the temperature of the first memory unit is higher than a first predetermined value and the temperature of the second memory unit is lower than a second predetermined value.

11. The method according to claim 10, wherein
the first predetermined value is equal to the second predetermined value.

12. The method according to claim 10, wherein
the first predetermined value is higher than the second predetermined value.

13. The method according to claim 10, further comprising:
in response to the command, accessing the first memory unit at a first data transfer rate, when the temperature of the first memory unit is lower than the first predetermined value, and at a second data transfer rate that is lower than the first data transfer rate when the temperatures of the semiconductor memory units are all higher than the second predetermined value.

14. The method according to claim 10, wherein
the second memory unit has the lowest of temperatures detected by the temperature sensing unit.

15. The method according to claim 10, further comprising:
calculating a total data size of data that have been written in each of the plurality of semiconductor memory units since a predetermined time.

16. The method according to claim 15, wherein
the total data size of data that have been written in the second memory unit is the smallest of the total data sizes that have been written in the semiconductor memory units.

17. The method according to claim 15, further comprising:
in response to the command,
accessing the first memory unit at a first data transfer rate, when the first temperature is lower than the first predetermined value; and
accessing one of the plurality of semiconductor memory units for which the total data size of data that have been written therein is the smallest, at a second data transfer rate that is slower than the first data transfer rate, when the temperatures of the plurality of semiconductor memory units are all higher than the second predetermined value.

18. The method according to claim 10, wherein
the temperature of the first sensor is measured using a first temperature sensor positioned on the first memory unit, and the temperature of the second sensor is measured using a second sensor positioned on the second memory unit.

19. A semiconductor device connectable to a host, comprising:
a plurality of semiconductor memory units, which includes first and second memory units;
a temperature sensing unit configured to detect temperatures of the plurality of semiconductor memory units, the temperature sensing unit including a first sensor positioned to detect a temperature of the first memory unit, as a first temperature, and a second sensor positioned to detect a temperature of the second memory unit, as a second temperature; and
a controller configured to
receive a command to access the first memory unit from the host, and
in response to the command, access the second memory unit and not the first memory unit, when the second temperature is lower than the first temperature.

20. The semiconductor device according to claim 19, wherein
the controller is further configured to determine a total data size of data that have been written in each of the plurality of semiconductor memory units since a predetermined time, and
the total data size of data that have been written in the second memory unit is the smallest of the total data sizes that have been written in the semiconductor memory units.
